(19) United States
(12) Patent Application Publication
(10) Pub. No.: US 2023/0260768 A1
(43) Pub. Date: Aug. 17, 2023

(54) PLASMA DISCHARGE UNIFORMITY CONTROL USING MAGNETIC FIELDS

(71) Applicant: Lam Research Corporation, Fremont, CA (US)

(72) Inventors: Theodoros Panagopoulos, Los Gatos, CA (US); Alexei M. Marakhtanov, Alexei, CA (US); Bing Ji, Pleasanton, CA (US); Anthony de la Llera, Fremont, CA (US); John P. Holland, San Jose, CA (US); Dong Woo Paeng, Albany, CA (US)

(21) Appl. No.: 18/013,480

(22) PCT Filed: Aug. 30, 2021
(86) PCT No.: PCT/US2021/048276

§ 371 Date: Dec. 28, 2022

Related U.S. Application Data
(60) Provisional application No. 63/080,513, filed on Sep. 18, 2020.

(51) Int. Cl. H01J 37/34; H01L 21/311

(52) U.S. Cl. CPC H01J 37/3402; H01L 21/31116; H01J 2237/24564; H01J 37/32935

(57) ABSTRACT

Methods, systems, apparatuses, and computer programs are presented for controlling plasma discharge uniformity using magnetic fields. A substrate processing apparatus includes a vacuum chamber with a processing zone for processing a substrate. The apparatus further includes a magnetic field sensor to detect a first signal representing an axial magnetic field and a second signal representing a radial magnetic field associated with the vacuum chamber. The apparatus includes at least two magnetic field sources to generate an axial supplemental magnetic field and a radial supplemental magnetic field through the processing zone of the vacuum chamber. The apparatus includes a magnetic field controller coupled to the magnetic field sensor and the at least two magnetic field sources. The magnetic field controller adjusts at least one characteristic of one or more of the axial supplemental magnetic field and the radial supplemental magnetic field based on the first signal and the second signal.

### CLAIM OF PRIORITY

This application claims the benefit of priority to U.S. Patent Application Ser. No. 63/080,513, filed on Sep. 18, 2020, which is incorporated by reference herein in its entirety.

### TECHNICAL FIELD

The subject matter disclosed herein generally relates to methods, systems, and machine-readable storage media for controlling etch rate and plasma uniformity using magnetic fields in plasma-based substrate manufacturing, such as capacitively coupled plasma (CCP) or inductively coupled plasma (ICP) substrate manufacturing.

### BACKGROUND

Semiconductor substrate processing systems are used to process semiconductor substrates by techniques including etching, physical vapor deposition (PVD), chemical vapor deposition (CVD), plasma-enhanced chemical vapor deposition (PECVD), atomic layer deposition (ALD), plasma-enhanced atomic layer deposition (PEALD), pulsed deposition layer (PDL), plasma-enhanced pulsed deposition layer (PEPDL), and resist removal. One type of semiconductor substrate processing apparatus is a plasma processing apparatus using CCP that includes a vacuum chamber containing upper and lower electrodes, where a radio frequency (RF) power is applied between the electrodes to excite a process gas into plasma for processing semiconductor substrates in the reaction chamber. Another type of semiconductor substrate processing apparatus is a plasma processing apparatus ICP.

In semiconductor substrate processing systems, such as the CCP-based or ICP-based vacuum chambers for manufacturing substrates, etch uniformity and ion tilt at the substrate center are influenced by plasma density uniformity, which has shown sensitivity to weak magnetic fields. For example, plasma density uniformity in CCP-based and ICP-based vacuum chambers can be influenced by magnetic fields associated with magnetized chamber components (which may be associated with a magnetic field strength of 5-10 Gauss) as well as other external magnetic fields including the Earth's magnetic field (which may have a magnetic field strength of 0.25-0.65 Gauss) or other ambient magnetic fields (which may have a magnetic field strength of 0.4-0.5 Gauss).

Currently, tuning plasma uniformity, particularly at the center of the substrate and across the substrate surface, is a challenge. Changing the dimension of the ground electrode within the chamber, gas and chemistry flows or the frequency content of delivered radio frequency (RF) are the main factors used to control the plasma uniformity. However, the magnetization of processing chamber components as well as exposure to external magnetic fields influences plasma density uniformity and varies greatly from chamber to chamber within a manufacturing location, as well as between chambers at different manufacturing locations. Improvements in hardware design and utilization of process knobs have thus far addressed the industry's needs for stringent plasma uniformity requirements. Nevertheless, uniformity specifications have become increasingly demanding and additional techniques are needed to achieve extremely uniform densities across the entire substrate surface. The present disclosure seeks to address, amongst other things, the drawbacks associated with conventional techniques for plasma density uniformity.

The background description provided herein is to generally present the context of the disclosure. It should be noted that the information described in this section is presented to provide the skilled artisan some context for the following disclosed subject matter and should not be considered as admitted prior art. More specifically, work of the presently named inventors, to the extent it is described in this background section, as well as aspects of the description that may not otherwise qualify as prior art at the time of filing, are neither expressly nor impliedly admitted as prior art against the present disclosure.

### SUMMARY

Methods, systems, and computer programs are presented for controlling etch rate and plasma uniformity using magnetic fields in substrate manufacturing. One general aspect includes a substrate processing apparatus. The apparatus includes a vacuum chamber including a processing zone for processing a substrate using plasma. The apparatus further includes a magnetic field sensor configured to detect a first signal representing an axial magnetic field and a second signal representing a radial magnetic field associated with the vacuum chamber. The radial magnetic field is a magnetic field that is parallel to the substrate and orthogonal to the axial magnetic field. The apparatus further includes at least two magnetic field sources configured to generate an axial supplemental magnetic field and a radial supplemental magnetic field through the processing zone of the vacuum chamber. The apparatus further includes a magnetic field controller coupled to the magnetic field sensor and the at least two magnetic field sources. The magnetic field controller is configured to adjust at least one characteristic of one or more of the axial supplemental magnetic field and the radial supplemental magnetic field based on the first signal and the second signal.

One general aspect includes a method for processing a substrate using a vacuum chamber. The method includes detecting a first signal representing an axial magnetic field within a processing zone of the vacuum chamber, where the processing zone is for processing the substrate using plasma. The method further includes detecting a second signal representing a radial magnetic field within the processing zone. The radial magnetic field is a magnetic field that is parallel to the substrate and orthogonal to the axial magnetic field. A magnitude of the first signal representing the axial magnetic field and a magnitude of the second signal representing the radial magnetic field is determined at a plurality of locations within the processing zone. The method further includes generating using at least two magnetic field sources, an axial supplemental magnetic field, and a radial supplemental magnetic field through the processing zone of the vacuum chamber based on the determined magnitudes of the first and second signals.

One general aspect includes a non-transitory machine-readable storage medium including instructions that, when executed by a machine, cause the machine to perform operations including detecting a first signal representing an axial magnetic field within a processing zone of a vacuum chamber, the processing zone for processing a substrate using plasma. A second signal representing a radial magnetic field within the processing zone is detected. The radial magnetic field is a magnetic field that is parallel to the substrate and orthogonal to the axial magnetic field. A magnitude of the first signal representing the axial magnetic field and a magnitude of the second signal representing the radial magnetic field is determined as a plurality of locations within the processing zone. An axial supplemental magnetic field and a radial supplemental magnetic field through the processing zone of the vacuum chamber are generated using at least two magnetic field sources based on the determined magnitudes of the first and second signals.

### BRIEF DESCRIPTION OF THE DRAWINGS

Various ones of the appended drawings merely illustrate example embodiments of the present disclosure and cannot be considered as limiting its scope.

FIG. 1 illustrates a vacuum chamber, such as an etching chamber, for manufacturing substrates using CCP, according to some example embodiments.

FIG. 2 illustrates a vacuum chamber enclosed by a magnetic shield structure and application of axial and radial magnetic fields to improve control of etch rate and plasma uniformity, according to some example embodiments.

FIG. 3A illustrates a perspective view of a vacuum chamber with supplemental axial and radial magnetic fields within a processing zone with CCP, according to some example embodiments.

FIG. 3B illustrates a top view of the vacuum chamber of FIG. 3A, according to some example embodiments.

FIG. 3C illustrates a side view of the vacuum chamber of FIG. 3A, according to some example embodiments.

FIG. 4 and FIG. 5 illustrate an axial magnetic field effect on plasma uniformity within a vacuum chamber, according to some example embodiments.

FIG. 6 illustrates a radial magnetic field effect on plasma uniformity within a vacuum chamber, according to some example embodiments.

FIG. 7, FIG. 8, and FIG. 9 illustrate a combined effect of an axial magnetic field and a radial magnetic field on plasma uniformity within a vacuum chamber, according to some example embodiments.

FIG. 10A illustrates a perspective view of a vacuum chamber with a single-coil used as a magnetic field source for axial and radial supplemental magnetic fields, according to some example embodiments.

FIG. 10B is a side view of the vacuum chamber of FIG. 10A illustrating mounting options for the magnetic field source, according to some example embodiments.

FIG. 11A illustrates a vacuum chamber with a single-coil used as a magnetic field source for axial and radial supplemental magnetic fields, according to some example embodiments.

FIG. 11B is a graph illustrating the magnitude of the axial and radial supplemental magnetic fields and the ratio of axial to radial magnitudes within the vacuum chamber of FIG. 11A, according to some example embodiments.

FIG. 12A illustrates a vacuum chamber with two coils used as a combined magnetic field source for axial and radial supplemental magnetic fields, according to some example embodiments.

FIG. 12B is a graph illustrating the magnitude of the axial and radial supplemental magnetic fields resulting from the two coils in FIG. 12A, when the number of turns and current through one of the coils is fixed, according to some example embodiments.

FIG. 12C is a graph illustrating the magnitude of the axial and radial supplemental magnetic fields resulting from the two coils in FIG. 12A, when the current through both coils is fixed but the number of turns in one of the coils changes, according to some example embodiments.

FIG. 13A illustrates a vacuum chamber with four coils used as a combined magnetic field source for axial and radial supplemental magnetic fields, according to some example embodiments.

FIG. 13B is a graph illustrating the ratio of axial to radial magnitudes as well as the magnitude of the axial and radial supplemental magnetic fields resulting from the four coils in FIG. 13A, according to some example embodiments.

FIG. 14 illustrates a vacuum chamber with different types of magnetic sensors and a magnetic field controller to configure one or more supplemental magnetic fields for improving plasma uniformity, according to some example embodiments.

FIG. 15 is a flowchart of a method for processing a substrate using a vacuum chamber, according to some example embodiments.

FIG. 16 is a block diagram illustrating an example of a machine upon which one or more example method embodiments may be implemented, or by which one or more example embodiments may be controlled.

### DETAILED DESCRIPTION

Example methods, systems, and computer programs are directed to controlling etch rate and plasma uniformity using magnetic fields in substrate manufacturing equipment. Examples merely typify possible variations. Unless explicitly stated otherwise, components and functions are optional and may be combined or subdivided, and operations may vary in sequence or be combined or subdivided. In the following description, for purposes of explanation, numerous specific details are set forth to provide a thorough understanding of example embodiments. It will be evident to one skilled in the art, however, that the present subject matter may be practiced without these specific details.

Substrate uniformity across the substrate surface is challenging to control since it depends on etch process conditions. When conditions change, uniformity may change as well. Static solutions to control plasma uniformity (such as adjusting the ground electrode dimension) may not perform efficiently over a wide range of process conditions. Solutions involving process parameters may lead to unwanted side effects when modified to address uniformity.

Techniques discussed herein use axial and radial magnetic fields to control plasma uniformity within the vacuum chamber. As used herein, the term “axial magnetic field” indicates a magnetic field that is orthogonal to a surface of a substrate within a vacuum chamber. As used herein, the term “radial magnetic field” indicates a magnetic field that is parallel to a surface of the substrate within the vacuum chamber. The disclosed techniques are based on the versatility and effectiveness of combined radial and axial magnetic fields. More specifically, the radial magnetic field enhances the plasma density across the substrate, while the axial magnetic field suppresses the plasma density at the substrate center, leading to edge high profiles (e.g., when the substrate radius r is greater than 80 mm). In this regard, a combination of both radial and axial magnetic fields may he used for controlling plasma density across the entire surface of the substrate within a vacuum chamber of a substrate processing apparatus (such as CCP-based or ICP-based substrate processing apparatuses).

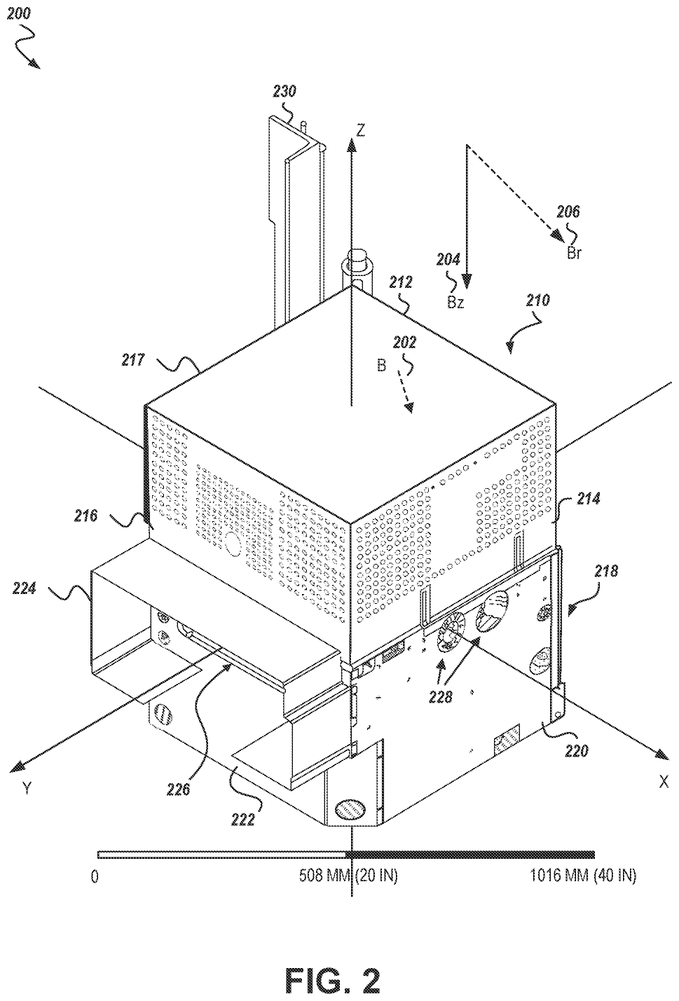

In some aspects and using the disclosed techniques, an existing radial magnetic field and an existing axial magnetic field may be detected, and an axial supplemental magnetic field and a radial supplemental magnetic field may be generated so that the resulting radial magnetic field and axial magnetic field within the chamber reach desired threshold values. More specifically, one or more magnetic field sensors may be used to detect a residual magnetic field (ΔB) within the processing zone of the vacuum chamber, which is based on an existing radial magnetic field and an existing axial magnetic field. For example, the magnetic sensors may detect the magnitude (Bz) of the axial magnetic field and the magnitude (Br) of the radial magnetic field forming the residual magnetic field detected within a vacuum chamber. At least two magnetic field sources may be used to generate an axial supplemental magnetic field and a radial supplemental magnetic field so that the magnitudes of the resulting axial and radial magnetic fields reach threshold values or a ratio of the magnitudes is adjusted to reach the desired threshold value. Various techniques and options for configuring radial and axial magnetic fields to improve plasma uniformity across the substrate surface are illustrated in connection with FIG. 2-FIG. 16.

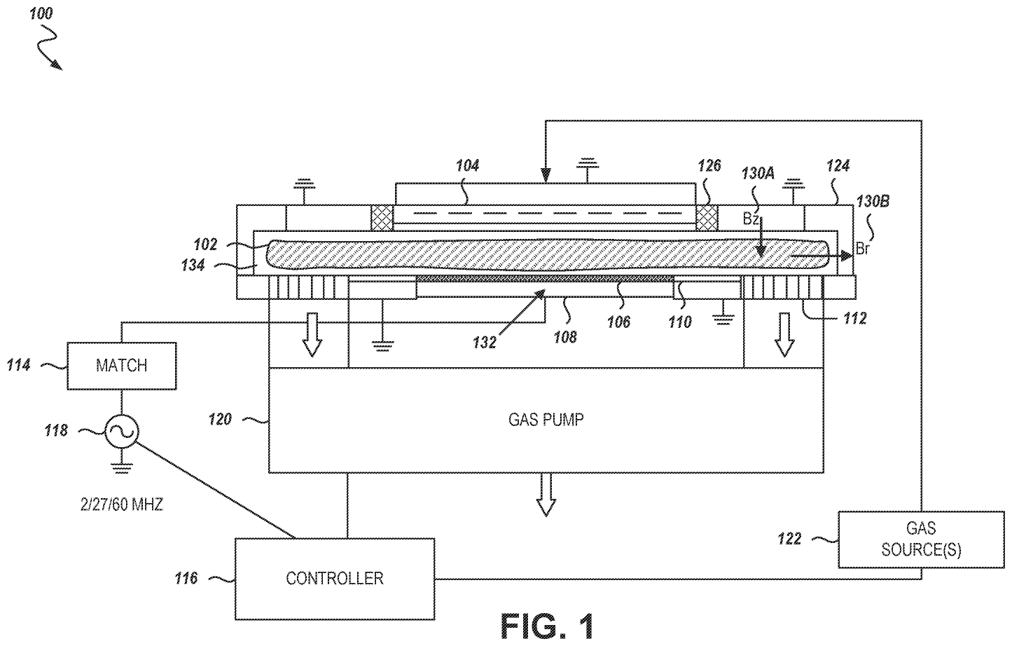

FIG. 1 illustrates a vacuum chamber 100 (e.g., an etching chamber) for manufacturing substrates using CCP, according to one embodiment. Exciting an electric field between two electrodes is one of the methods to obtain radio frequency (RF) gas discharge in a vacuum chamber. When an oscillating voltage is applied between the electrodes, the discharge obtained is referred to as a CCP discharge.

Plasma 102 may be created utilizing stable feedstock gases to obtain a wide variety of chemically reactive by-products created by the dissociation of the various molecules caused by electron-neutral collisions. The chemical aspect of etching involves the reaction of the neutral gas molecules and their dissociated by-products with the molecules of the to-be-etched surface and producing volatile molecules, which can be pumped away. When a plasma is created, the positive ions are accelerated from the plasma across a space-charge sheath separating the plasma from chamber walls to strike the substrate surface with enough energy to remove material from the substrate surface. This is known as ion bombardment or ion sputtering. Some industrial plasmas, however, do not produce ions with enough energy to efficiently etch a surface by purely physical means.

A controller 116 manages the operation of the vacuum chamber 100 by controlling the different elements in the chamber, such as RF generator 118, gas sources 122, and gas pump 120. In one embodiment, fluorocarbon gases, such as CF₄ and C₄F₈, are used in a dielectric etch process for their anisotropic and selective etching capabilities, but the principles described herein can be applied to other plasma-creating gases. The fluorocarbon gases are readily dissociated into chemically reactive by-products that include smaller molecular and atomic radicals. These chemically reactive by-products etch away the dielectric material.

The vacuum chamber 100 illustrates a processing chamber with a top electrode 104 and a bottom electrode 108. The top electrode 104 may be grounded or coupled to an RF generator (not shown), and the bottom electrode 108 is coupled to the RF generator 118 via a matching network 114. The RF generator 118 provides RF power in one or multiple (e.g., two or three) different RF frequencies. According to the desired configuration of the vacuum chamber 100 for a particular operation, at least one of the three RF frequencies may be turned on or off. In the embodiment shown in FIG. 1, the RF generator 118 is configured to provide, e.g., 2 MHz, 27 MHz, and 60 MHz frequencies, but other frequencies are also possible.

The vacuum chamber 100 includes a gas showerhead on the top electrode 104 to input process gas into the vacuum chamber 100 provided by the gas source(s) 122, and a perforated confinement ring 112 that allows the gas to be pumped out of the vacuum chamber 100 by gas pump 120. In some example embodiments, the gas pump 120 is a turbomolecular pump, but other types of gas pumps may be utilized.

When substrate 106 is present in the vacuum chamber 100, silicon focus ring 110 is situated next to substrate 106 such that there is a uniform RF field at the bottom surface of the plasma 102 for uniform etching on the surface of the substrate 106. The embodiment of FIG. 1 shows a triode reactor configuration where the top electrode 104 is surrounded by a symmetric RF ground electrode 124. Insulator 126 is a dielectric that isolates the ground electrode 124 from the top electrode 104. Other implementations of the vacuum chamber 100, including ICP-based implementations, are also possible without changing the scope of the disclosed embodiments.

The substrate 106 can include, for example, wafers (e.g., having a diameter of 100 mm, 150 mm, 200 mm, 300 mm, 450 mm, or larger) and comprising, for example, elemental-semiconductor materials (e.g., silicon (Si) or germanium (Ge)) or compound-semiconductor materials (e.g., silicon germanium (SiGe) or gallium arsenide (GaAs)). Additionally, other substrates include, for example, dielectric materials such as quartz or sapphire (onto which semiconductor materials may be applied).

Each frequency generated by the RF generator 118 may be selected for a specific purpose in the substrate manufacturing process. In the example of FIG. 1, with RF powers provided at 2 MHz, 27 MHz, and 60 MHz, the 2 MHz RF power provides ion energy control, and the 27 MHz and 60 MHz powers provide control of the plasma density and the dissociation patterns of the chemistry. This configuration, where each RF power may he turned ON or OFF, enables certain processes that use ultra-low ion energy on the substrates or wafers, and certain processes (e.g., soft etch for low-k materials) where the ion energy has to be low (e.g., under 700 or 200 eV).

In another embodiment, a 60 MHz RF power is used on the top electrode 104 to get ultra-low energies and very high density. This configuration allows chamber cleaning with high-density plasma when substrate 106 is not in the vacuum chamber 100 while minimizing sputtering on the electrostatic chuck (ESC) surface. The ESC surface is exposed when substrate 106 is not present, and any ion energy on the surface should he avoided, which is why the bottom 2 MHz and 27 MHz power supplies may be off during cleaning.

In some aspects, the vacuum chamber 100 is exposed to external magnetic fields, such as the Earth's magnetic field or other ambient magnetic fields (e.g., magnetic fields from magnetized components of the vacuum chamber such as a hoist as illustrated in FIG. 2). The resulting residual magnetic field in the vacuum chamber 100 is undesirable as it may negatively impact etch rate and plasma uniformity especially around a center region 132 of the substrate 106 within the processing zone 134. In an example embodiment, an axial magnetic field 130A with magnitude Bz and a radio magnetic field 130B with magnitude Br may be introduced within the processing zone 134 so that a ratio of the magnitudes Bz/Br reaches the desired threshold, facilitating plasma uniformity across the surface of the substrate 106 within the processing zone 134. Various techniques to generate axial and radial magnetic fields or tuning plasma uniformity across the substrate surface are discussed in connection with FIG. 2-FIG. 16.

FIG. 2 illustrates a vacuum chamber enclosed by a magnetic shield structure and application of axial and radial magnetic fields to improve control of etch rate and plasma uniformity, according to some example embodiments. Referring to FIG. 2, a vacuum chamber, such as vacuum chamber 100 of FIG. 1, may be enclosed by a magnetic shield structure 200 to reduce the effects of an external magnetic field.

In an example embodiment, the magnetic shield structure 200 can include a top shielding portion 210 and a bottom shielding portion 218, where each shielding portion may include multiple shielding sub-portions as shown in FIG. 2. For example, the top shielding portion 210 can include shielding sub-portions 212, 214, 216, and 217. The bottom shielding portion 218 can include shielding sub-portions 220, 222, and 224. In some aspects, the magnetic shield structure 200 can include one or more openings 228 to accommodate various facilities used by the vacuum chamber, such as openings to accommodate RF components and communication links, ventilation, gas delivery, heaters, high-voltage clamps, substrate delivery mechanisms, etc.

In an example embodiment, the magnetic shield structure 200 can be manufactured from a high permeability material with a thickness of at least 40 mils. In an example embodiment, the various shielding sub-portions of the magnetic shield structure 200 can be bolted to (or securely attached via other means) to various surfaces of the vacuum chamber.

In an example embodiment, the shielding sub-portion 224 can be formed as a tunnel surrounding the vacuum chamber opening 226, which is used for delivery and removal of the substrate from the processing zone with the CCP.

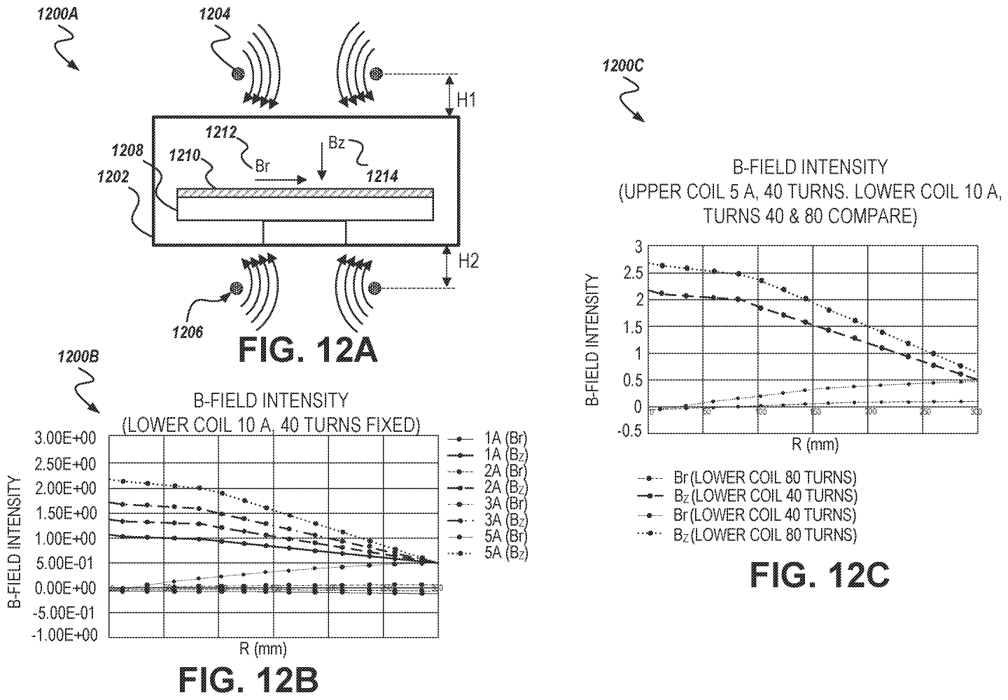

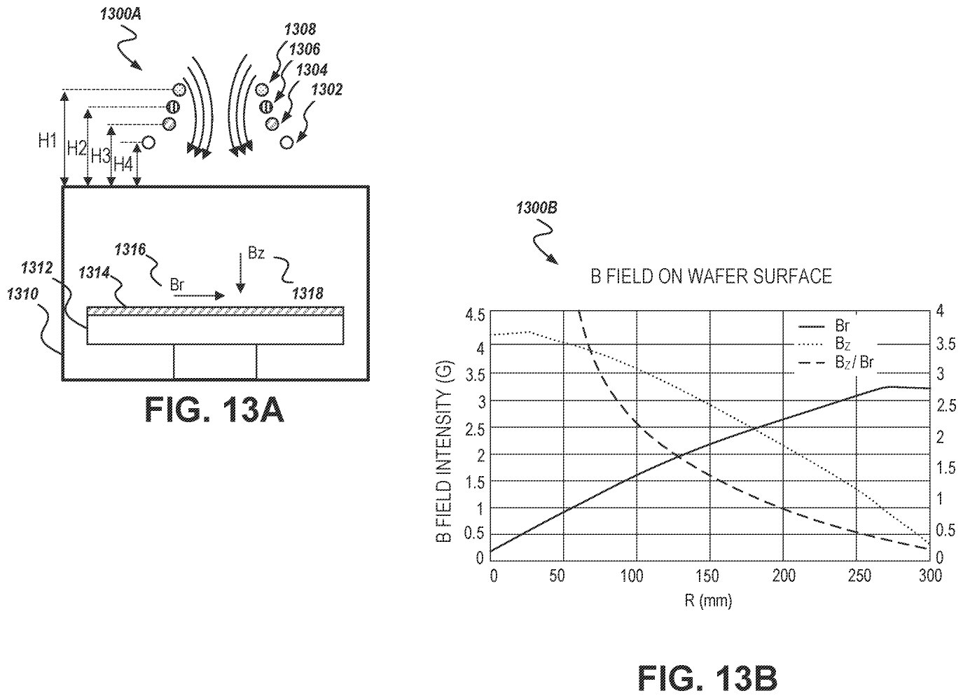

Due to imperfections of the magnetic shield structure 200 (e.g., the one or more openings 228 for accommodating vacuum chamber facilities), a residual magnetic field 202 can exist under the magnetic shield structure 200 and within the vacuum chamber 100 as a result of the external magnetic field including magnetic fields from magnetized chamber components (e.g., a magnetized hoist 230). In an example embodiment, one or more supplemental magnetic fields, such as an axial supplemental magnetic field 204 (with magnitude Bz) and a radial supplemental magnetic field 206 (with magnitude Br) be generated (e.g., using the techniques disclosed in connection with FIG. 12A and 13A) within the vacuum chamber 100 to counteract the effects of the residual magnetic field 208 (e.g., achieve a resulting radial magnetic field and an axial magnetic field with a specific ratio of their magnitudes) and tune plasma uniformity across the substrate surface.

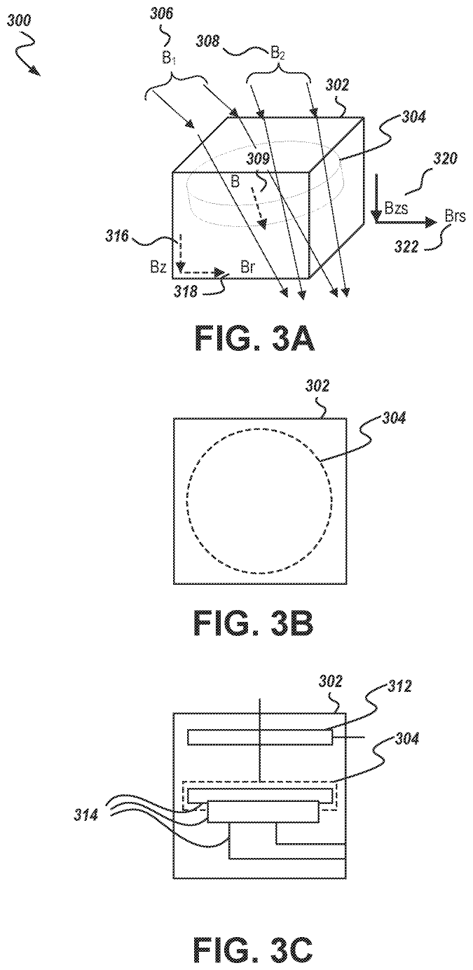

FIG. 3A illustrates a perspective view 300 of a vacuum chamber 302 with supplemental axial and radial magnetic fields within a processing zone with CCP, according to some example embodiments. Referring to FIG. 3A, the vacuum chamber 302 can be exposed to external magnetic fields, such as a first external magnetic field 306 and a second external magnetic field 308, collectively forming a residual magnetic field 309 within a processing zone 304 (e.g., a volume filled with the CCP inside the vacuum chamber 302). The residual magnetic field 309 may be formed by an axial magnetic field 316 (with magnitude Bz) and a radial magnetic field 318 (with magnitude Br).

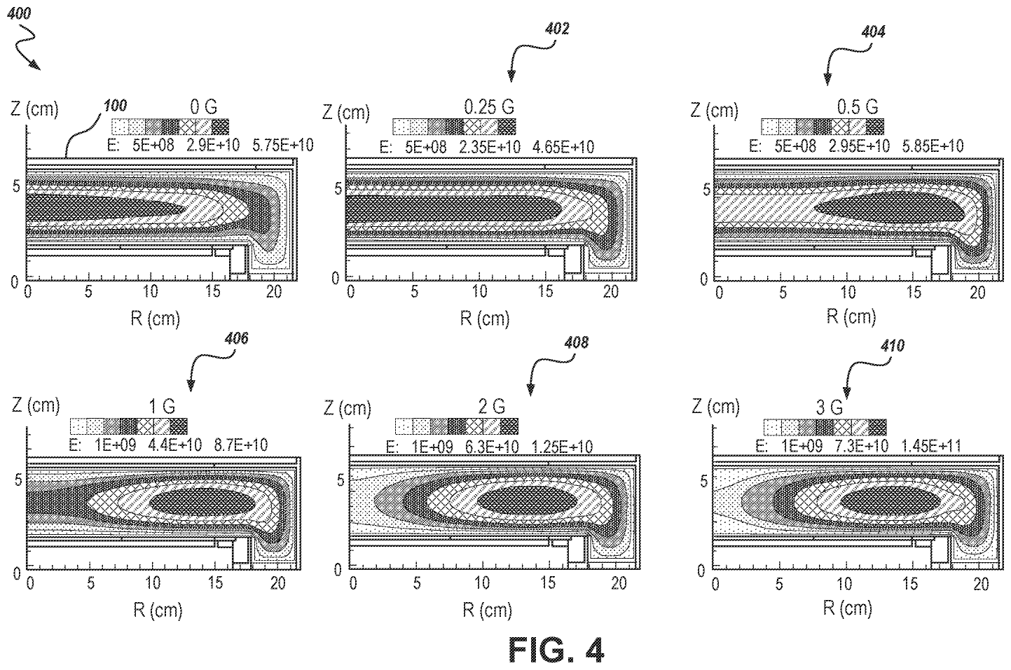

In an example embodiment, the effects of the residual magnetic field 309 on plasma uniformity across substrate surface within the processing zone 304 can be mitigated by introducing a supplemental magnetic field comprising an axial supplemental magnetic field 320 and a radial supplemental magnetic field 322, with corresponding magnitudes Bzs and Brs. The resulting magnetic field within the processing zone 304 (e.g., including the residual magnetic field 309 and the supplemental magnetic field comprising the axial supplemental magnetic fields 320 and the radial supplemental magnetic field 322) may be configured to result in greater plasma uniformity across the substrate surface within the processing zone 304. More specifically, multiple magnetic field sources (e.g., as discussed in connection with FIG. 12A and FIG. 13A) may be used to generate the supplemental magnetic fields so that the desired ratio of the magnitudes of the axial supplemental magnetic field 320 and the radial supplemental magnetic field 322 is achieved. FIG. 4-FIG. 9 illustrate that a combination of both radial and axial magnetic fields can control plasma density across the entire surface of a substrate within a processing zone. In this regard, multiple magnetic field sources can be used to generate the axial and radial magnetic fields so that a ratio of their magnitudes (e.g., Bz/Br) may be adjusted to achieve a desired plasma uniformity across the substrate surface.

FIG. 3B illustrates a top view of the vacuum chamber 302 of FIG. 3A, according to sonic example embodiments. FIG. 3C illustrates a side view of the vacuum chamber 302 of FIG. 3A, according to some example embodiments. Referring to FIG. 3C, the vacuum chamber 302 can include a top plate 312 as well as various facilities 314 used in connection with processing a substrate within the processing zone 304 (e.g., RF components and communication links, gas delivery, heaters, high-voltage clamps, substrate delivery mechanisms, etc.). The top plate 312 can include thereto-couplers and auxiliary components to handle the gas flow, power for temperature control, mechanical components associated with gas vacuum functionalities, etc.

in an example embodiment, the top plate 312 or the facilities 314 may be used for mounting at least one magnetic field source that can generate one or more supplemental magnetic fields (e.g., an axial supplemental magnetic field and a radial supplemental magnetic field) to counter the residual magnetic field within the vacuum chamber 302 and achieve the desired ratio magnitudes Bz/Br for during plasma uniformity across the substrate surface.

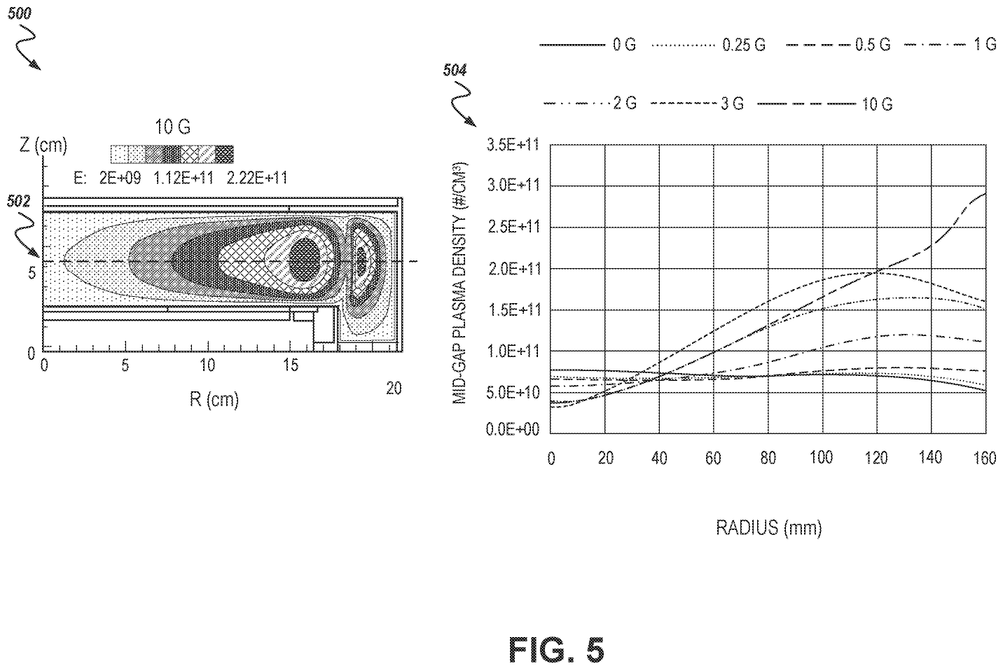

FIG. 4 and FIG. 5 illustrate an axial magnetic field effect on plasma uniformity within a vacuum chamber, according to some example embodiments. Referring to FIG. 4 and FIG. 5, there are illustrated graphs 400, 402, 404, 406, 408, 410, and 500 of axial magnetic field effects when RF power of 300 W and 60 MHz is supplied at a bottom electrode of a vacuum chamber (e.g., the bottom electrode 108 of the vacuum chamber 100). Graph 400 illustrates plasma distribution when no magnetic field (e.g., the magnetic field is 0 Gauss in magnitude or 0 G) is applied to vacuum chamber 100. Graphs 402-410 and 500 illustrate the plasma uniformity when an axial magnetic field with respective magnitudes of 0.25 G (in graph 402), 0.5 G (in graph 404), 1 G (in graph 406), 2 G (in graph 408), 3 G (in graph 410), and 10 G (in graph 500) are applied within the vacuum chamber 100. As seen in FIG. 4 in FIG. 5, the plasma distribution within the vacuum chamber changes as the magnitude of the applied axial magnetic field increases.

Graph 504 in FIG. 5 illustrates the mid-gap plasma density across a centerline 502 of the vacuum chamber 100 when the axial magnetic fields of magnitude 0 G, 0.25 G, 0.5 G, 1 G, 2 G, 3 G, and 10 G are applied. As seen in graph 504 (as well as graphs 400-410 and 500), plasma distribution shifts from being higher near the substrate center (at 0 G) to a more uniform distribution across the substrate (e.g., at 0.25 G), to being higher near the substrate edge (e.g., at 1 G-10 G magnitudes). Applying an axial magnetic field increases the electron loss rate to the upper and lower electrodes while decreasing electron mobility in the radial direction. Due to the existence of higher electric fields near the substrate edge (fringing effect), electrons get confined in that region creating a peak in plasma density near that location. In this regard, by applying an axial magnetic field, the density near the substrate center (e.g., the chamber centerline 502) is suppressed, while the density near the substrate edge gets enhanced (e.g., due to limited electron diffusion to adjacent radius due to decreased electron mobility).

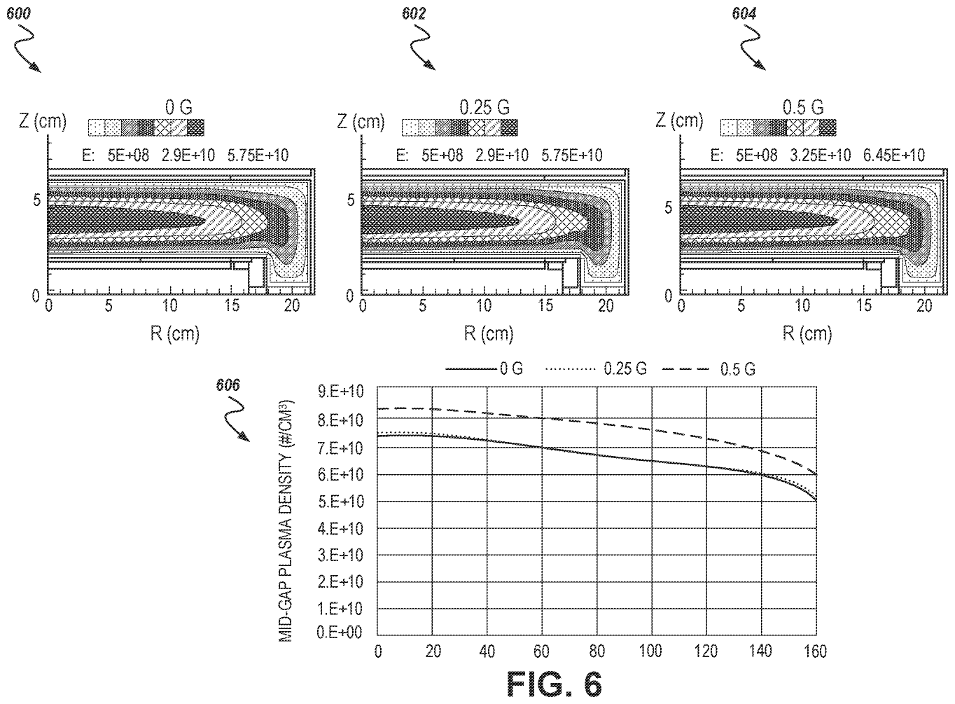

FIG. 6 illustrates a radial magnetic field effect on plasma uniformity within a vacuum chamber, according to some example embodiments. Referring to FIG. 6, there are illustrated graphs 600, 602, and 604 of radial magnetic field effects when RF power of 300 W and 60 MHz is supplied at a bottom electrode of a vacuum chamber (e.g., the bottom electrode 108 of the vacuum chamber 100). Graph 600 illustrates plasma distribution when no magnetic field (e.g., the magnetic field is 0 Gauss in magnitude or 0 G) is applied to vacuum chamber 100. Graphs 602 and 604 illustrate the plasma uniformity when a radial magnetic field with respective magnitudes of 0.25 G (in graph 602) and 0.5 G (in graph 604) are applied within the vacuum chamber 100. Graph 606 in FIG. 6 illustrates the mid-gap plasma density across a centerline of the vacuum chamber 100 when the radial magnetic fields of magnitude 0 G, 0.25 G, and 0.5 G are applied. As seen in graph 604, the radial magnetic field slightly increases plasma density at a magnitude of 0.5 G. In this regard, applying a radial magnetic field parallel to the substrate surface can decrease electron losses to upper and lower electrodes. A reduction of loss rate results in increased bulk plasma density. Consequently, adjusting the intensity of the radial magnetic field may be used for tailoring the plasma density in a desired range of values.

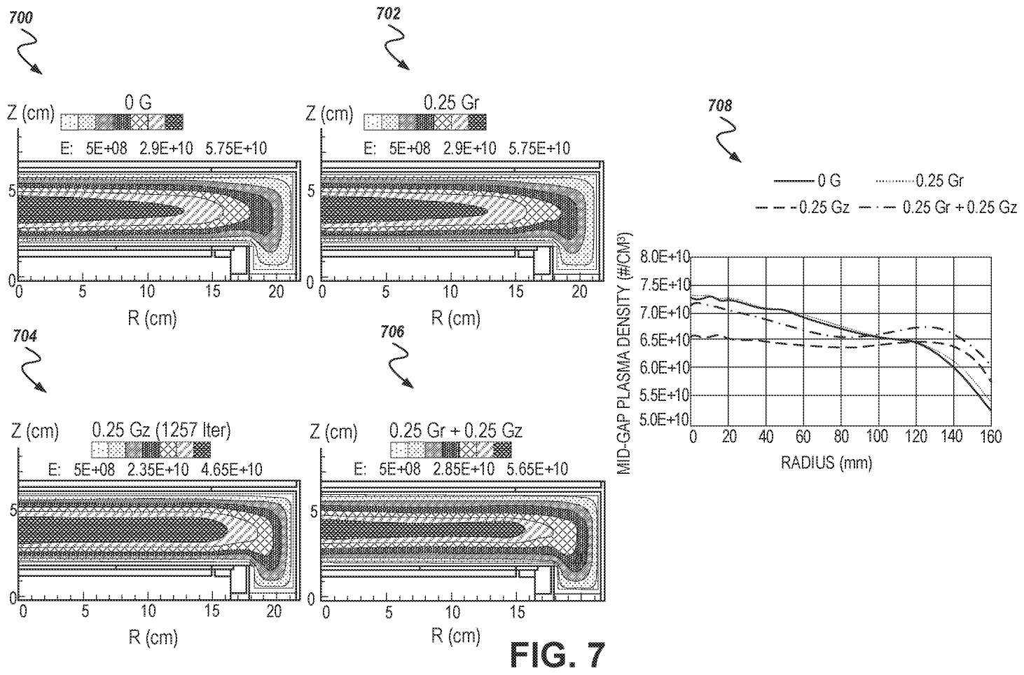

FIG. 7, FIG. 8, and FIG. 9 illustrate a combined effect of an axial magnetic field and a radial magnetic field on plasma uniformity within a vacuum chamber, according to some example embodiments.

Referring to FIG. 7, there are illustrated graphs 700, 702, 704, and 706 of combined magnetic field effects (e.g., a combination of both axial and radial magnetic fields) when RF power of 300 W and 60 MHz is supplied at a bottom electrode of a vacuum chamber (e.g., the bottom electrode 108 of the vacuum chamber 100). Graph 700 illustrates plasma distribution when no magnetic field (e.g., the magnetic field is 0 Gauss in magnitude or 0 G) is applied to vacuum chamber 100. Graph 702 illustrates the plasma uniformity when a radial magnetic field with a magnitude 0.25 Gr is applied (where Gr is a Gauss measure for a radial magnetic field). Graph 704 illustrates the plasma uniformity when an axial magnetic field with a magnitude 0.25 Gz is applied (where Gz is a Gauss measure for an axial magnetic field). Graph 706 illustrates the plasma uniformity when a radial magnetic field with a magnitude of 0.25 G and an axial magnetic field with a magnitude 0.25 Gz are applied within the vacuum chamber. Graph 708 illustrates the mid-gap plasma density across a centerline of the vacuum chamber 100 when the magnetic fields of magnitude 0 G, 0.25 Gr, 0.25 Gz, and 0.25 Gr with 0.25 Gz are applied.

Referring to FIG. 8, there are illustrated graphs 800, 802, 804, and 806 of combined magnetic field effects (e.g., a combination of both axial and radial magnetic fields) when RF power of 300 W and 60 MHz is supplied at a bottom electrode of a vacuum chamber (e.g., the bottom electrode 108 of the vacuum chamber 100). Graph 800 illustrates plasma distribution when no magnetic field (e.g., the magnetic field is 0 Gauss in magnitude or 0 G) is applied to vacuum chamber 100. Graph 802 illustrates the plasma uniformity when a radial magnetic field with a magnitude 0.5 Gr is applied. Graph 804 illustrates the plasma uniformity when an axial magnetic field with a magnitude 0.5 Gz is applied. Graph 806 illustrates the plasma uniformity when a radial magnetic field with a magnitude of 0.5 G and an axial magnetic field with a magnitude 0.5 Gz are applied within the vacuum chamber. Graph 808 illustrates the mid-gap plasma density across a centerline of the vacuum chamber 100 when the magnetic fields of magnitude 0 G, 0.5 Gr, 0.5 Gz, and 0.5 Gr with 0.5 Gz are applied.

Referring to FIG. 9, there are illustrated graphs 900, 902, 904, and 906 of combined magnetic field effects (e.g., a combination of both axial and radial magnetic fields) when RF power of 300 W and 60 MHz is supplied at a bottom electrode of a vacuum chamber (e.g., the bottom electrode 108 of the vacuum chamber 100). Graph 900 illustrates plasma distribution when no magnetic field (e.g., the magnetic field is 0 Gauss or 0 G) is applied to the vacuum chamber 100. Graph 902 illustrates the plasma uniformity when a radial magnetic field with a magnitude 0.5 Gr and an axial magnetic field with a magnitude of 0.25 Gz are applied. Graph 904 illustrates the plasma uniformity when a radial magnetic field with a magnitude 0.25 Gr and an axial magnetic field with a magnitude of 0.5 Gz are applied. Graph 906 illustrates the plasma uniformity when a radial magnetic field with a magnitude 0.5 Gr and an axial magnetic field with a magnitude of 0.5 Gz are applied within the vacuum chamber. Graph 908 illustrates the mid-gap plasma density across a centerline of the vacuum chamber 100 when the magnetic fields of magnitude 0 G, 0.5 Gr with 0.25 Gz, 0.25 Gr with 0.5 Gz, and 0.5Gr with 0.5 Gz are applied.

Based on the graph data in FIG. 4-FIG. 9, applying both a radial magnetic field and an axial magnetic field can balance the above-mentioned trends associated with individual application of axial or radial magnetic fields, providing a tuning knob for incremental plasma density changes near the substrate center or the substrate edge. In this regard, by adjusting the ratio Bz/Br of magnitudes of the axial magnetic field and the radial magnetic field, plasma uniformity may be tuned across the substrate surface within a vacuum chamber. In an example embodiment, controlling the ratio Bz/Br may be achieved by individually controlling the current (or other characteristics) of the multiple magnetic field sources, such as discussed in connection with FIG. 12A-FIG. 13B. In some embodiments, when existing magnetic fields (e.g., a residual magnetic field) is already present in the vacuum chamber, the magnitudes of axial and radial magnetic fields that are associated with the residual magnetic field are determined, and an axial supplemental magnetic field and a radial supplemental magnetic field may be generated so that a resulting (e.g., combined) magnetic field with desired magnitudes of the radial and axial components (e.g., magnitudes Bz and Br) is achieved.

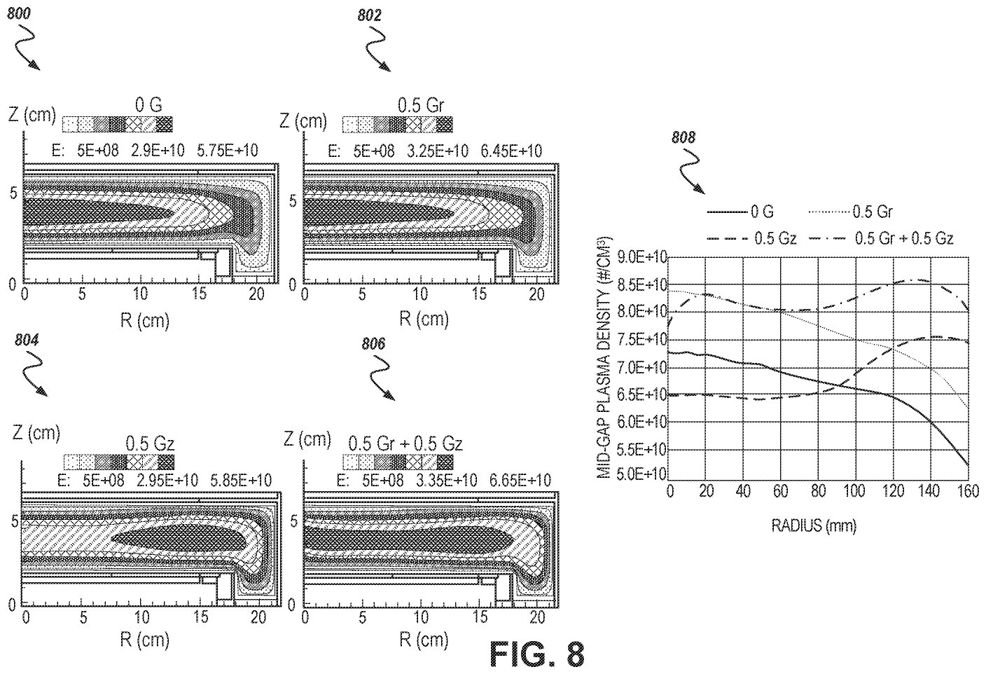

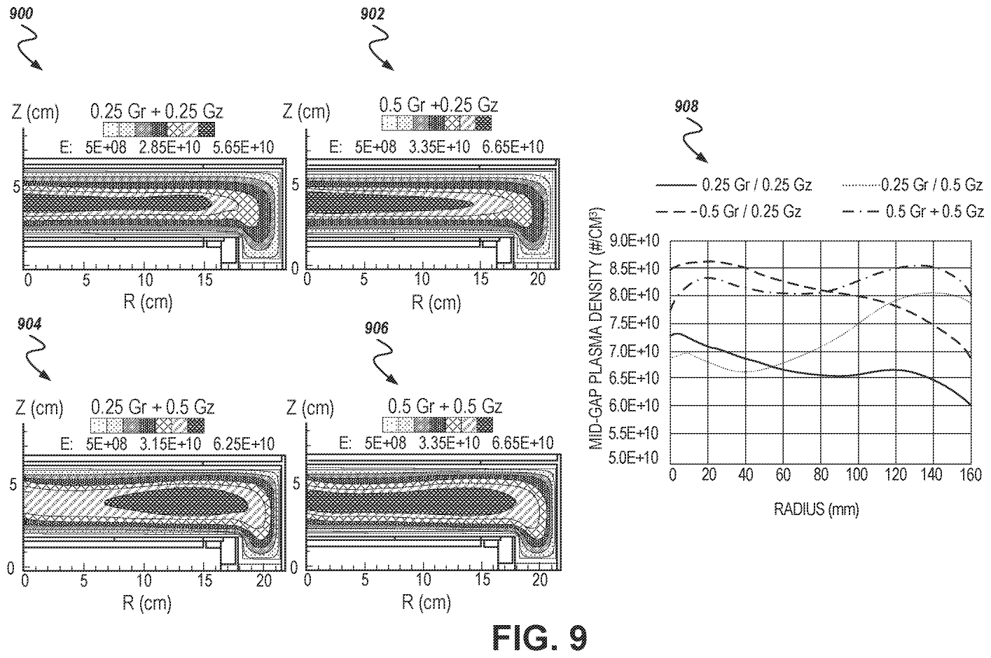

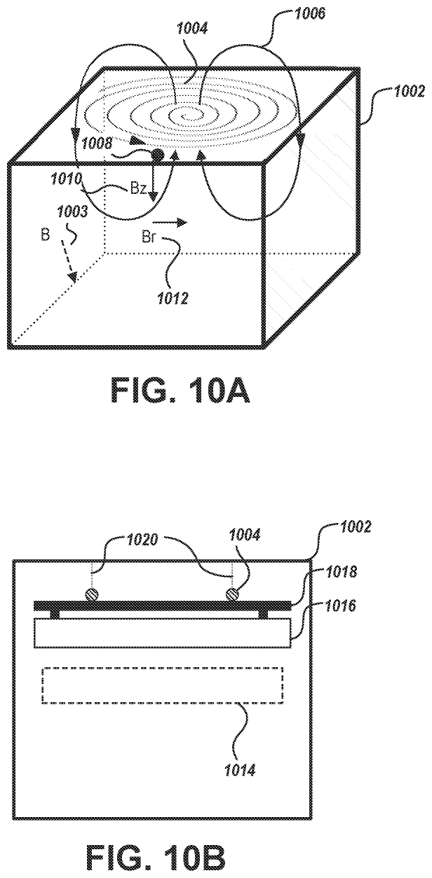

FIG. 10A illustrates a perspective view of a vacuum chamber 1002 with a single-coil used as a magnetic field source for axial and radial magnetic fields, according to some example embodiments. Referring to FIG. 10A, the vacuum chamber 1002 may experience a residual magnetic field 1003 measured at location 1008 within the processing zone of the vacuum chamber. In some aspects, a magnetic field source 1004 (e.g., a single-coil) may be configured to generate a supplemental magnetic field 1006 within the vacuum chamber 1002. The supplemental magnetic field 1006 may include a radial magnetic field 1010 with a magnitude Bz and a radial magnetic field 1012 with a magnitude Br. One or more characteristics of the supplemental magnetic field may be configured (e.g., current, number of turns, etc. for coil 1004) to adjust the uniformity of plasma distribution within the vacuum chamber.

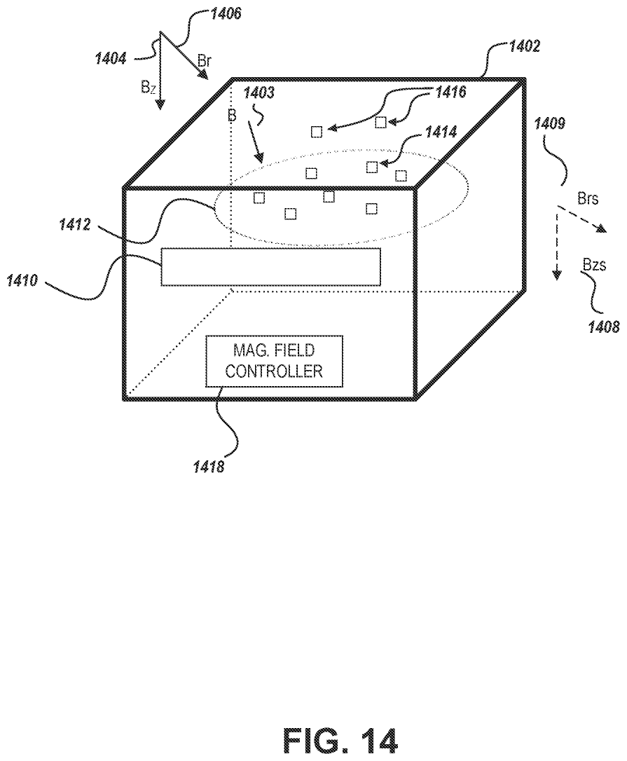

In an example embodiment, the residual magnetic field 1003 may be detected and measured by a magnetic field sensor placed at or near location 1008. Example magnetic field sensors that can be used to detect residual magnetic fields are illustrated in connection with FIG. 14. Additionally, a magnetic field controller (e.g., as illustrated in FIG. 14) may be used to adjust one or more characteristics of the supplemental magnetic field 1006. For example, the magnetic field controller may adjust a current (e.g., a direct current (DC)) of the coil 1004, thereby changing the magnitude of the supplemental magnetic field 1006 (and the corresponding magnitudes Bz and Br). In some aspects, the current may be adjusted so that the magnitude of the supplemental magnetic field 1006 combined with the magnitude of the residual magnetic field 1003 results in the desired magnitude Bz or Br so that a uniform plasma distribution within the vacuum chamber is achieved. In other aspects, the magnetic field controller may adjust different characteristics (e.g., number of turns, distance to chamber centerline, etc.) so that a desired total Bz and/or Br are achieved within the chamber.

FIG. 10B is a side view of the vacuum chamber 1002 of FIG. 10A illustrating mounting options for the magnetic field source 1004, according to some example embodiments. Referring to FIG. 10B, in an example embodiment, the magnetic field source 1004 (e.g., a coil) may be mounted internally, within the vacuum chamber 1002, and in proximity to the processing zone 1014. In an example embodiment, the coil 1004 may be mounted on a pedestal 1018 secured to the top plate 1016 of the vacuum chamber 1002. In an example embodiment, the coil 1004 may also be mounted to an inside surface of the vacuum chamber 1002 (e.g., a top surface as illustrated in FIG. 10B) via connections 1020.

In an example embodiment, the vacuum chamber 1002 may be enclosed within a magnetic shield structure such as a magnetic shield structure 200, and the coil 1004 may be secured within the magnetic shield structure but outside of the vacuum chamber 1002 (e.g., on an internal surface of the magnetic shield structure). In an example embodiment, coil 1004 may be placed outside of the magnetic shield structure and the vacuum chamber 1002. In an example embodiment, multiple coils may be used as magnetic field sources to generate axial and radial supplemental magnetic fields (e.g., as illustrated in FIG. 12A and FIG. 13A), where each coil may be positioned differently (e.g., inside or outside the vacuum chamber).

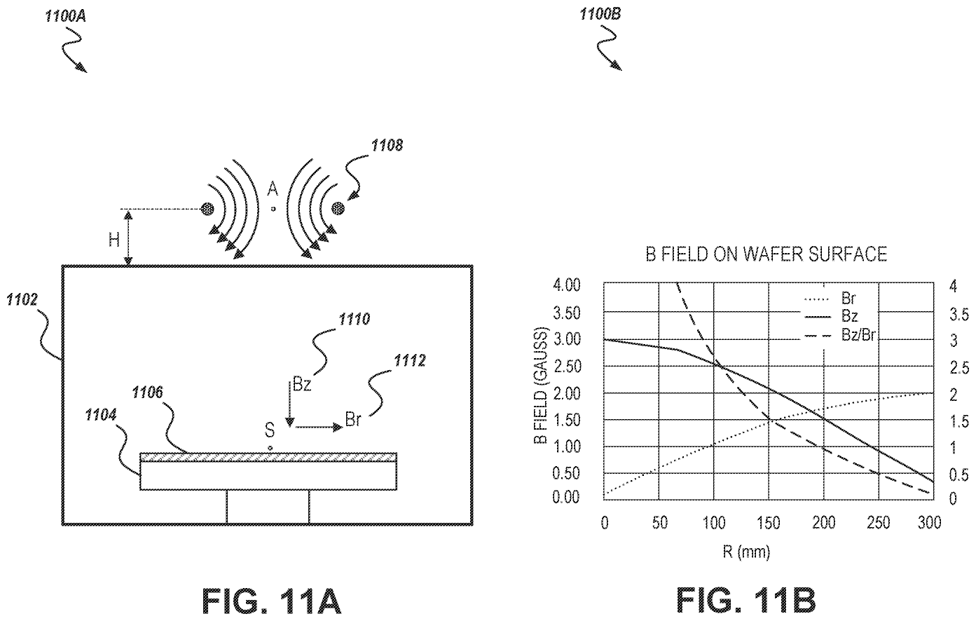

FIG. 11A illustrates a diagram 1100A of a vacuum chamber 1102 with a single-coil 1108 used as a magnetic field source for axial and radial supplemental magnetic fields, according to some example embodiments. Referring to FIG. 11A, the single-coil 1108 is used as a source for an axial supplemental magnetic field 1110 with a magnitude Bz and a radial supplemental magnetic field 1112 with a magnitude Br.

FIG. 11B is a graph 1100B illustrating the magnitude of the axial and radial supplemental magnetic fields and the ratio of axial to radial magnitudes within the vacuum chamber of FIG. 11A, according to some example embodiments.

During substrate processing of a substrate 1106 placed on a pedestal 1104, the single-coil 1108 is activated resulting in an axial supplemental magnetic field 1110 and a radial supplemental magnetic field 1112. The magnitude of the axial supplemental magnetic field 1110 is higher at location A (closer to the single-coil 1108) than at location S (closer to a midpoint of the substrate 1106). As illustrated in graph 1100B, Bz various from about 3 G near the substrate center to about 2.1 G near the substrate edge (for a 300 mm diameter substrate). The magnitude Br of the radial supplemental magnetic field 1112 various from about 0.1 G near the substrate center to about 1.5 G near the substrate edge. The ratio of Bz/Br near the substrate edge is about 1.5.

In an example embodiment, the location of the single-coil 1108 (e.g., inside or outside the vacuum chamber 1102), the distance H of the single-coil to a top surface of the vacuum chamber (or the distance of the single coil to the substrate 1106), the current through the single coil 1108, or other characteristics of the single-coil may be varied (e.g., during the setup of the vacuum chamber or dynamically during processing) to achieve a different amplitude of the Bz/Br ratio for tuning plasma uniformity across the substrate surface. However, a change in any of the characteristics of the single-coil 1108 results in proportionate changes of Bz and Br, while the ratio Bz/Br remains unchanged.

In an example embodiment, to achieve tunability of the ratio Bz/Br and more optimal plasma uniformity across a substrate surface in a vacuum chamber, multiple magnetic field sources (e.g., at least two magnetic field sources) may be used to generate axial and radial magnetic fields within the vacuum chamber, where processing characteristics of the magnetic field sources may be adjusted individually (e.g., at set up time or dynamically, during the substrate processing). Example embodiments using multiple magnetic field sources are discussed in connection with FIG. 12A-FIG. 13B.

FIG. 12A illustrates a diagram 1200A of a vacuum chamber 1202 with two coils (e.g., coils 1204 and 1206) used as a combined magnetic field source for axial and radial supplemental magnetic fields, according to some example embodiments. Referring to FIG. 12A, the coils 1204 and 1206 are used as a combined source for an axial supplemental magnetic field 1214 with a magnitude Bz and a radial supplemental magnetic field 1212 with a magnitude Br.

As illustrated in FIG. 12A, the substrate 1210 is placed on a pedestal 1208 within the vacuum chamber 1202. Coil 1204 is placed at a distance of H1 from a top surface of the vacuum chamber 1202 and coil 1206 is placed at a distance of H2 from a bottom surface of the vacuum chamber 1202. Even though coils 1204 and 1206 are illustrated as both being outside the vacuum chamber 1202, the disclosure is not limited in this regard and any of the coils 1204 and 1206 may be disposed inside or outside of the vacuum chamber 1202.

During substrate processing of a substrate 1210 placed on the pedestal 1208, the coils 1204 and 1206 are activated resulting in the axial supplemental magnetic field 1214 and the radial supplemental magnetic field 1212. FIG. 12B is a graph 1200B illustrating the magnitude of the axial and radial supplemental magnetic fields (1214 and 1212) resulting from the two coils 1204 and 1206 in FIG. 12A, when the number of turns and current through one of the coils is fixed, according to some example embodiments. More specifically, graph 1200B illustrates the magnitudes Bz and Br when coil 1206 is fixed at 40 turns and current 10 A, while the current through coil 1204 varies from 1 A to 5 A.

FIG. 12C is a graph 1200C illustrating the magnitude of the axial and radial supplemental magnetic fields (1214 and 1212) resulting from the two coils 1204 and 1206 in FIG. 12A, when the current through both coils is fixed but the number of turns in one of the coils changes, according to some example embodiments. More specifically, graph 1200C illustrates the magnitudes Bz and Br when coil 1204 is fixed at 40 turns and current 5 A, with coil 1206 having a current of 10 A and varying between 40 and 80 turns.

As seen from FIG. 12B and FIG. 12C, if coil 1206 is fixed at 10 A and 40 turns, Bz is approximately equal to Br at current 5 A for coil 1204. Additionally, if the turns of the coil 1206 are increased to 80 (or if the current of lower coil 1206 is increased to 20 A), the Br magnitude may be further reduced.

In an example embodiment, the location of the coils 1206 and 1204 (e.g., inside or outside the vacuum chamber 1202), the distances H1 and H2 to the corresponding top and bottom surfaces of the vacuum chamber (or the respective distances of the coils 1204 and 1206 to the substrate 1210), the current through each of the coils 1204 and 1206 (or any other processing characteristic of the coils) may be varied individually for each coil (e.g., by the magnetic field controller 1418 during the setup of the vacuum chamber or dynamically during processing) to achieve a different Bz/Br ratio for optimal tuning plasma uniformity across the substrate surface.

FIG. 13A illustrates a diagram 1300A of a vacuum chamber 1310 with four coils (e.g., coils 1302, 1304, 1306, and 1308) used as a combined magnetic field source for axial and radial supplemental magnetic fields, according to some example embodiments. Referring to FIG. 13A, the coils 1302-1308 are used as a combined source for an axial supplemental magnetic field 1318 with a magnitude Bz and a radial supplemental magnetic field 1316 with a magnitude Br.

As illustrated in FIG. 13A, the substrate 1314 is placed on a pedestal 1312 within the vacuum chamber 1310. Coils 1308, 1306, 1304, and 1302 are placed at corresponding distances H1, H2, H3, and H4 from a top surface of the vacuum chamber 1310. Even though coils 1302-1308 are illustrated as being outside the vacuum chamber 1310, the disclosure is not limited in this regard, and any of the coils 1302-1308 may be disposed inside or outside of the vacuum chamber 1310 (while remaining parallel to each other and the substrate 1314).

In an example embodiment and as illustrated in FIG. 13A, coils 1302-1308 have different diameters. However, the disclosure is not limited in this regard, and two or more of the coils 1302-1308 may have the same diameter. Additionally, even though FIG. 13A illustrates only for coils 1302-1308 for generating the axial and radial supplemental magnetic fields, the disclosure is not limited in this regard and a greater number of coils may be used as well, which can be arranged in a different configuration on multiple sides of the vacuum chamber 1310.

During substrate processing of a substrate 1314 placed on the pedestal 1312, the coils 1302-1308 are activated resulting in the axial supplemental magnetic field 1318 and the radial supplemental magnetic field 1316. FIG. 13B is a graph 1300B illustrating the ratio of axial to radial magnitudes (Bz/Br) as well as the magnitude of the axial and radial supplemental magnetic fields resulting from a current of 5 A in the four coils in FIG. 13A, according to some example embodiments. As seen from FIG. 13B, Bz varies from about 4.2 G near the substrate center to about 3.2 G near the substrate edge, while Br varies from about 0.4 G near the substrate center to about 2.4 G near the substrate edge.

In an example embodiment, the location of the coils 1302-1308 (e.g., inside or outside the vacuum chamber 1310), the distances H1-H4 to the top surface of the vacuum chamber (or the respective distances of the coils 1302-1308 to the substrate 1314), the current through each of the coils 1302-1308 (or any other processing characteristic of the coils) may be varied individually for each coil (e.g., by the magnetic field controller 1418 during the setup of the vacuum chamber or dynamically during processing) to achieve a different Bz/Br ratio for optimal tuning plasma uniformity across the substrate surface.

FIG. 14 illustrates a vacuum chamber 1402 with different types of magnetic sensors and a magnetic field controller to configure one or more supplemental magnetic fields for improving plasma uniformity, according to some example embodiments. Referring to FIG. 14, vacuum chamber 1402 may be exposed to external magnetic fields resulting in a residual magnetic field 1403 within the vacuum chamber, which is composed of a radial magnetic field 1404 with a magnitude Bz and a radial magnetic field 1406 with a magnitude Br.

In an example embodiment, the vacuum chamber 1402 includes a magnetic field controller 1418, which can be the same as controller 116 in FIG. 1. The magnetic field controller 1418 comprises suitable circuitry, logic, interfaces, and/or code and is configured to receive magnetic field sensor data and adjust one or more characteristics of a supplemental magnetic field generated by at least one magnetic field source. In an example embodiment, a smart wafer 1412 may be loaded within the processing zone of the vacuum chamber 1402 from the opening 1410. The smart wafer 1412 may include a plurality of sensors 1414 (e.g., magnetic field sensors) that are configured to detect and measure residual magnetic fields (e.g., residual magnetic field 1403) after the smart wafer 1412 is placed within the processing zone inside the vacuum chamber 1402. In an example embodiment, the magnetic field controller 1418 may also use one or more standalone sensors 1416 (e.g., magnetic field sensors) to detect and measure residual magnetic fields (such as residual magnetic field 1403) as well as magnetic fields in specific directions (e.g., measure axial and radial magnetic fields).

In an example embodiment, the magnetic field controller 1418 may use the sensors 1414 and/or 1416 to detect the magnitude and direction of the residual magnetic field 1403. The magnetic field controller 1403 may adjust at least one characteristic of one or more supplemental magnetic fields, including one or more of an axial supplemental magnetic field 1408 (with a magnitude Bzs) and/or a radial supplemental magnetic field 1409 (with a magnitude Brs), to achieve a combined magnetic field with a specific Bz/Br ratio of magnitudes. For example, the magnetic field controller 1418 may adjust the current through the at least one magnetic field source that generates the supplemental magnetic field (e.g., adjust the current individually for multiple magnetic field sources such as the magnetic field sources illustrated in FIG. 12A and FIG. 13A). Additionally, the magnetic field controller 1418 may activate or deactivate one or more magnetic field sources of a plurality of available magnetic field sources (such as multiple coils configured as illustrated in FIG. 12A, FIG. 13A, or another configuration), to achieve the desired magnitude Bz of a radial magnetic field within the vacuum chamber 1402, the desired magnitude Br of an axial magnetic field within the vacuum chamber 1402, or the desired ratio of magnitudes Bz/Br.

In an example embodiment, the vacuum chamber 1402 may further include a plasma density sensor (not illustrated in FIG. 14) coupled to the magnetic field controller 1418. In some aspects, the plasma density sensor may also be coupled to one or more of the magnetic field sensors 1414 and/or 1416 and may be configured to measure the density of the plasma within the vacuum chamber.

In an example embodiment, the sensors 1414 and/or 1416 may be used for an initial magnetic field measurement so that the magnetic field controller 1418 may perform adjustments resulting in generating a supplemental magnetic field with desired magnitude and direction so that a total (resulting) magnetic field with the desired Bz, Br, or Bz/Br is achieved.

In some embodiments, periodic measurements and adjustments may be performed using sensors 1414 and/or 1416. In an example embodiment, standalone sensors 1416 may be used for automatic (dynamic) measurements and adjustments in the characteristics of the supplemental magnetic fields. In an example embodiment, one magnetic field sensor (or a set of magnetic field sensors) may be used in connection with a single magnetic field source, so that different sensors may be associated with different magnetic field sources. In an example embodiment, the magnetic field controller 1418 may communicate wirelessly with sensors 1414 and 1416 to receive sensor data.

In an example embodiment, any of the sensors 1414 and/or 1416 can include optical or thermal sensors configured to measure plasma density. In this case, the magnetic field controller 1418 is also configured to generate the axial supplemental magnetic field 1408 (with the magnitude Bzs) and the radial supplemental magnetic field 1409 (with the magnitude Brs), to achieve a combined magnetic field with a specific Bz/Br ratio of magnitudes based on the plasma density measured by the sensors 1414 and/or 1416.

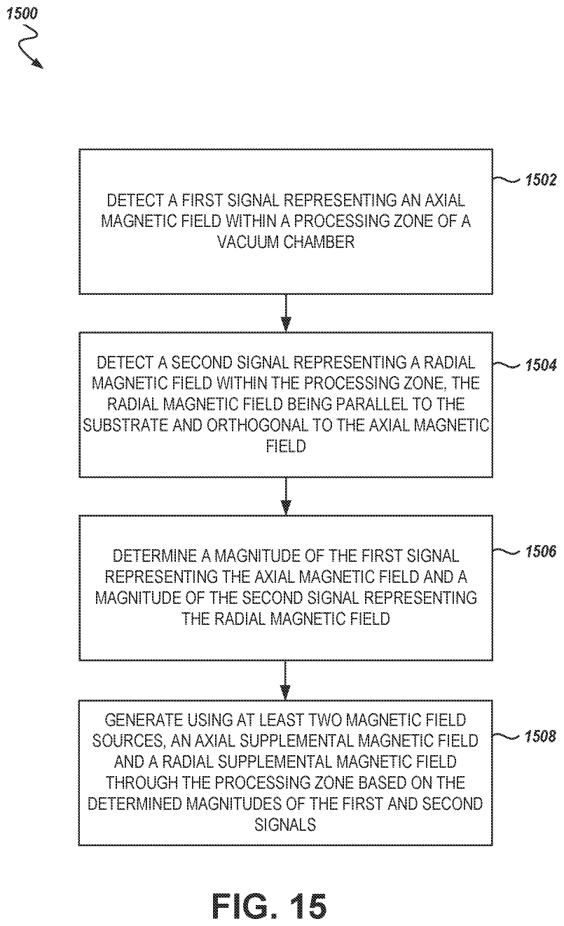

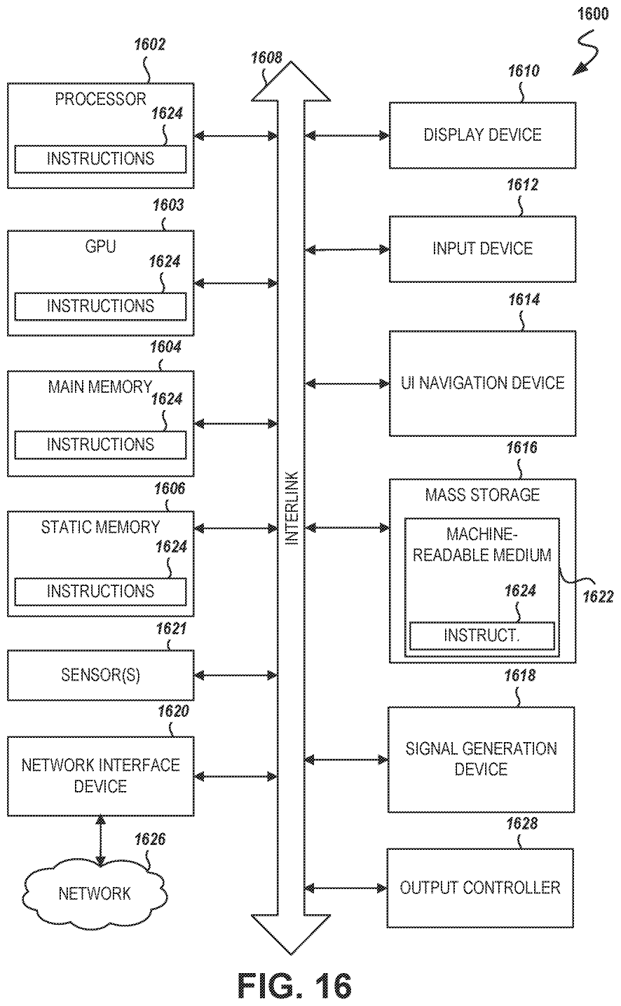

FIG. 15 is a flowchart of a method 1500 for processing a substrate using a vacuum chamber, according to some example embodiments. Method 1500 includes operations 1502, 1504, 1506, and 1508, which may be performed by a magnetic field controller such as magnetic field controller 1418 of FIG. 14 or processor 1602 of FIG. 16. Referring to FIG. 15, at operation 1502, a first signal representing an axial magnetic field within a processing zone of the vacuum chamber is detected, where the processing zone is for processing a substrate using plasma. For example, one of the sensors 1414 or 1416 detects a first signal representing the axial magnetic field 1404 within the processing zone of the vacuum chamber 1402. At operation 1504, a second signal representing a radial magnetic field within the processing zone is detected, where the radial magnetic field is a magnetic field that is parallel to the substrate and orthogonal to the axial magnetic field. For example, the magnetic sensor can further detect a second signal representing the radial magnetic field 1406. At operation 1506, a magnitude of the first signal representing the axial magnetic field and a magnitude of the second signal representing the radial magnetic field is determined at a plurality of locations within the processing zone. For example, a magnitude Bz of the first signal representing the axial magnetic field 1404 and a magnitude Br of the second signal representing the radial magnetic field 1406 is determined (e.g., by the magnetic field controller 1418). At operation 1508, an axial supplemental magnetic field and a radial supplemental magnetic field through the processing zone of the vacuum chamber generating using at least two magnetic field sources and based on the determined magnitudes of the first and second signals. For example, the axial supplemental magnetic field 1408 and the radial supplemental magnetic field 1409 are generated using at least two magnetic field sources (e.g., the magnetic field sources illustrated in connection with FIG, 12A and FIG. 13A) based on the determined magnitudes Bz and Br. For example, the axial and radial supplemental magnetic fields can be generated so that the resulting axial and supplemental magnetic fields (e.g., magnetic fields based on a combination of the existing/residual magnetic fields 1404 and 1406 and the supplemental magnetic fields 1409 and 1408) are generated by the at least two magnetic field sources with current, coil size (e.g., number of turns) or other characteristics of the magnetic field sources set individually so that the desired ratio of the magnitudes of the resulting axial and supplemental magnetic fields is achieved.

FIG. 16 is a block diagram illustrating an example of a machine 1600 upon or by which one or more example process embodiments described herein may be implemented or controlled. In alternative embodiments, the machine 1600 may operate as a standalone device or may be connected (e.g., networked) to other machines. In a networked deployment, the machine 1600 may operate in the capacity of a server machine, a client machine, or both in server-client network environments. In an example, the machine 1600 may act as a peer machine in a peer-to-peer (P2P) (or other distributed) network environment. Further, while only a single machine 1600 is illustrated, the term “machine” shall also be taken to include any collection of machines that individually or jointly execute a set (or multiple sets) of instructions to perform any one or more of the methodologies discussed herein, such as via cloud computing, software as a service (SaaS), or other computer cluster configurations.

Examples, as described herein, may include, or may operate by, logic, several components, or mechanisms. Circuitry is a collection of circuits implemented in tangible entities that include hardware (e.g., simple circuits, gates, logic). Circuitry membership may be flexible over time and underlying hardware variability. Circuitries include members that may, alone or in combination, perform specified operations when operating. In an example, the hardware of the circuitry may be immutably designed to carry out a specific operation (e.g., hardwired). In an example, the hardware of the circuitry may include variably connected physical components (e.g., execution units, transistors, simple circuits) including a computer-readable medium physically modified (e.g., magnetically, electrically, by the moveable placement of invariant massed particles) to encode instructions of the specific operation. In connecting the physical components, the underlying electrical properties of a hardware constituent are changed (for example, from an insulator to a conductor or vice versa). The instructions enable embedded hardware (e.g., the execution units or a loading mechanism) to create members of the circuitry in hardware via the variable connections to carry out portions of the specific operation when in operation. Accordingly, the computer-readable medium is communicatively coupled to the other components of the circuitry when the device is operating. In some aspects, any of the physical components may be used in more than one member of more than one circuitry. For example, under operation, execution units may be used in a first circuit of a first circuitry at one point in time and reused -by a second circuit in the first circuitry, or by a third circuit in a second circuitry, at a different time.

The machine (e.g., computer system) 1600 may include a hardware processor 1602 (e.g., a central processing unit (CPU), a hardware processor core, or any combination thereof), a graphics processing unit (GPU) 1603, a main memory 1604, and a static memory 1606, some or all of which may communicate with each other via an interlink (e.g., bus) 1608. The machine 1600 may further include a display device 1610, an alphanumeric input device 1612 (e.g., a keyboard), and a user interface (UI) navigation device 1614 (e.g., a mouse). In an example, the display device 1610, alphanumeric input device 1612, and UI navigation device 1614 may he a touch screen display. The machine 1600 may additionally include a mass storage device (e.g., drive unit) 1616, a signal generation device 1618 (e.g., a speaker), a network interface device 1620, and one or more sensors 1621, such as a Global Positioning System (GPS) sensor, compass, accelerometer, or another sensor. The machine 1600 may include an output controller 1628, such as a serial (e.g., universal serial bus (USB)), parallel, or other wired or wireless (e.g., infrared (IR), near field communication (NFC)) connection to communicate with or control one or more peripheral devices (e.g., a printer, card reader),

In an example embodiment, the hardware processor 1602 may perform the functionalities of the magnetic field controller 1418 discussed hereinabove, in connection with at least FIG. 14 and FIG. 15.

The mass storage device 1616 may include a machine-readable medium 1622 on which is stored one or more sets of data structures or instructions 1624 (e.g., software) embodying or utilized by any one or more of the techniques or functions described herein. The instructions 1624 may also reside, completely or at least partially, within the main memory 1604, within the static memory 1606, within the hardware processor 1602, or within the GPU 1603 during execution thereof by the machine 1600. In an example, one or any combination of the hardware processor 1602, the GPU 1603, the main memory 1604, the static memory 1606, or the mass storage device 1616 may constitute machine-readable media.

While the machine-readable medium 1622 is illustrated as a single medium, the term “machine-readable medium” may include a single medium or multiple media, (e.g., a centralized or distributed database, and/or associated caches and servers) configured to store the one or more instructions 1624.

The term “machine-readable medium” may include any medium that is capable of storing, encoding, or carrying instructions 1624 for execution by the machine 1600 and that cause the machine 1600 to perform any one or more of the techniques of the present disclosure, or that is capable of storing, encoding, or carrying data structures used by or associated with such instructions 1624. Non-limiting machine-readable medium examples may include solid-state memories and optical and magnetic media. In an example, a massed machine-readable medium comprises a machine-readable medium 1622 with a plurality of particles having invariant (e.g., rest) mass. Accordingly, massed machine-readable media are not transitory propagating signals. Specific examples of massed machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The instructions 1624 may further be transmitted or received over a communications network 1626 using a transmission medium via the network interface device 1620.

Implementation of the preceding techniques may be accomplished through any number of specifications, configurations, or example deployments of hardware and software. It should be understood that the functional units or capabilities described in this specification may have been referred to or labeled as components or modules, to more particularly emphasize their implementation independence. Such components may be embodied by any number of software or hardware forms. For example, a component or module may be implemented as a hardware circuit comprising custom very-large-scale integration (VLSI) circuits or gate arrays, off-the-shelf semiconductors such as logic chips, transistors, or other discrete components. A component or module may also be implemented in programmable hardware devices such as field-programmable gate arrays, programmable array logic, programmable logic devices, or the like. Components or modules may also be implemented in software for execution by various types of processors. An identified component or module of executable code may, for instance, comprise one or more physical or logical blocks of computer instructions, which may, for instance, be organized as an object, procedure, or function. Nevertheless, the executables of an identified component or module need not be physically located together but may comprise disparate instructions stored in different locations which, when joined logically together, comprise the component or module and achieve the stated purpose for the component or module.

Indeed, a component or module of executable code may be a single instruction, or many instructions, and may even be distributed over several different code segments, among different programs, and across several memory devices or processing systems. In particular, some aspects of the described process (such as code rewriting and code analysis) may take place on a different processing system (e.g., in a computer in a data center), than that in which the code is deployed (e.g., in a computer embedded in a sensor or robot). Similarly, operational data may be identified and illustrated herein within components or modules and may be embodied in any suitable form and organized within any suitable type of data structure. The operational data may be collected as a single data set or may be distributed over different locations including over different storage devices, and may exist, at least partially, merely as electronic signals on a system or network. The components or modules may be passive or active, including agents operable to perform desired functions.

### Additional Notes & Examples

Example 1 is a substrate processing apparatus, comprising: a vacuum chamber including a processing zone for processing a substrate using plasma; a magnetic field sensor configured to detect a first signal representing an axial magnetic field and a second signal representing a radial magnetic field associated with the vacuum chamber, the radial magnetic field being parallel to the substrate and orthogonal to the axial magnetic field; at least two magnetic field sources configured to generate an axial supplemental magnetic field and a radial supplemental magnetic field through the processing zone of the vacuum chamber; and a magnetic field controller coupled to the magnetic field sensor and the at least two magnetic field sources, the magnetic field controller configured to adjust at least one characteristic of one or more of the axial supplemental magnetic field and the radial supplemental magnetic field based on the first signal and the second signal.

In Example 2, the subject matter of Example 1 includes, wherein the magnetic field sensor is a wafer sensor placed within the processing zone of the vacuum chamber.

In Example 3, the subject matter of Example 2 includes, wherein the wafer sensor comprises an array of magnetic field sensors configured to measure one or more parameters of the axial magnetic field and the radial magnetic field at a plurality of locations within the processing zone; and wherein the magnetic field controller adjusts the at least one characteristic of the axial and radial supplemental magnetic fields based on the measured one or more parameters.

In Example 4, the subject matter of Examples 1-3 includes, wherein the magnetic field sensor is configured to measure a magnitude of the first signal representing the axial magnetic field and a magnitude of the second signal representing the radial magnetic field.

In Example 5, the subject matter of Example 4 includes, wherein the at least one characteristic comprises one or more of a magnitude and a direction of the axial supplemental magnetic field and the radial supplemental magnetic field.

In Example 6, the subject matter of Example 5 includes, wherein the at least two magnetic field sources comprise a first magnetic field source and a second magnetic field source that are parallel to each other, and wherein the magnetic field controller is configured to adjust one or more of the current through the first magnetic field source and current through the second magnetic field source to adjust one or more of the magnitude and the direction of the axial supplemental magnetic field and the radial supplemental magnetic field.

In Example 7, the subject matter of Example 6 includes, wherein the magnetic field controller is configured to adjust the current through the first magnetic field source independently of the current through the second magnetic field source.

In Example 8, the subject matter of Examples 6-7 includes, wherein the magnetic field controller is configured to adjust the current through the first magnetic field source and the current through the second magnetic field source until a ratio of the magnitude of the first signal representing the axial magnetic field and the magnitude of the second signal representing the radial magnetic field reaches a ratio threshold value.

In Example 9, the subject matter of Examples 6-8 includes, wherein the magnetic field controller is configured to adjust the current through the first magnetic field source and the current through the second magnetic field source until the magnitude of the first signal representing the axial magnetic field reaches a first threshold value and a magnitude of the second signal representing the radial magnetic field reaches a second threshold value.

In Example 10, the subject matter of Examples 1-9 includes, wherein the at least one characteristic of one or more of the axial supplemental magnetic field and the radial supplemental magnetic field comprises one or more of a number of windings in each of the at least two magnetic field sources; a distance from a first of the at least two magnetic field sources to the substrate; a distance from a second of the at least two magnetic field sources to the substrate; and a distance between the at least two magnetic field sources.

In Example 11, the subject matter of Examples 1-10 includes, wherein the at least two magnetic field sources comprise a plurality of coils, each coil comprising a plurality of windings.

In Example 12, the subject matter of Example 11 includes, wherein the plurality of coils is mounted externally to the vacuum chamber.

In Example 13, the subject matter of Examples 11-12 includes, wherein at least one of the plurality of coils is mounted internally to the vacuum chamber.

In Example 14, the subject matter of Examples 11-13 includes, wherein the plurality of coils comprises at least four coils that are parallel to each other and the substrate, and wherein the magnetic field controller is configured to adjust current through each of the at least four coils independently, based on a magnitude of one or more of the axial supplemental magnetic field and the radial supplemental magnetic field measured by the magnetic field sensor.

In Example 15, the subject matter of Examples 1-14 includes, wherein the substrate processing apparatus further comprises a plasma density sensor coupled to the magnetic field controller and configured to measure density of the plasma within the vacuum chamber, and wherein the magnetic field controller is configured to adjust current through each of the at least two magnetic field sources independently, based on the measured density of the plasma.

Example 16 is a method for processing a substrate using a vacuum chamber, the method comprising: detecting a first signal representing an axial magnetic field within a processing zone of the vacuum chamber, the processing zone for processing the substrate using plasma; detecting a second signal representing a radial magnetic field within the processing zone, the radial magnetic field being parallel to the substrate and orthogonal to the axial magnetic field; determining a magnitude of the first signal representing the axial magnetic field and a magnitude of the second signal representing the radial magnetic field at a plurality of locations within the processing zone; and generating using at least two magnetic field sources, an axial supplemental magnetic field, and a radial supplemental magnetic field through the processing zone of the vacuum chamber based on the determined magnitudes of the first and second signals.

In Example 17, the subject matter of Example 16 includes, adjusting current through at least one of the at least two magnetic field sources, to adjust one or more of a magnitude and a direction of the axial supplemental magnetic field and the radial supplemental magnetic field.

In Example 18, the subject matter of Example 17 includes, adjusting the current through the at least one of the at least two magnetic field sources independently, until a ratio of the magnitude of the first signal representing the axial magnetic field and the magnitude of the second signal representing the radial magnetic field reaches a ratio threshold value.

In Example 19, the subject matter of Examples 17-18 includes, adjusting the current through the at least one of the at least two magnetic field sources independently, until the magnitude of the first signal representing the axial magnetic field reaches a first threshold value and a magnitude of the second signal representing the radial magnetic field reaches a second threshold value,

Example 20 is a non-transitory machine-readable storage medium including instructions that, when executed by a machine, cause the machine to perform operations comprising: detecting a first signal representing an axial magnetic field within a processing zone of a vacuum chamber, the processing zone for processing a substrate using plasma; detecting a second signal representing a radial magnetic field within the processing zone, the radial magnetic field being parallel to the substrate and orthogonal to the axial magnetic field; determining a magnitude of the first signal representing the axial magnetic field and a magnitude of the second signal representing the radial magnetic field at a plurality of locations within the processing zone; and generating using at least two magnetic field sources, an axial supplemental magnetic field and a radial supplemental magnetic field through the processing zone of the vacuum chamber based on the determined magnitudes of the first and second signals.

In Example 21, the subject matter of Example 20 further including adjusting one or more of current through the first magnetic field source and current through the second magnetic field source to adjust one or more of a magnitude and a direction of the axial supplemental magnetic field and the radial supplemental magnetic field.

In Example 22, the subject matter of Example 21 further including adjusting the current through the at least two magnetic field sources independently, until a ratio of the magnitude of the first signal representing the axial magnetic field and the magnitude of the second signal representing the radial magnetic field reaches a ratio threshold value.

In Example 23, the subject matter of Examples 21-22 further includes adjusting the current through the at least two magnetic field sources independently, until the magnitude of the first signal representing the axial magnetic field reaches a first threshold value and a magnitude of the second signal representing the radial magnetic field reaches a second threshold value.

Example 24 is at least one machine-readable medium including instructions that, when executed by processing circuitry, cause the processing circuitry to perform operations to implement any of Examples 1-23.

Example 25 is an apparatus comprising means to implement any of Examples 1-23.

Example 26 is a system to implement any of Examples 1-23.

Example 27 is a method to implement any of Examples 1-23.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality are presented as separate components for example configurations may be implemented as a combined structure or component. Similarly, structures and functionality presented as a single component may be implemented as separate components. These and other variations, modifications, additions, and improvements fall within the scope of the subject matter herein.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

The claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within the scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to he regarded in an illustrative rather than a restrictive sense.

What is claimed is:

1. A substrate processing apparatus, comprising:
a vacuum chamber including a processing zone for processing a substrate using plasma;
a magnetic field sensor configured to detect a first signal representing an axial magnetic field and a second signal representing a radial magnetic field associated with the vacuum chamber, the radial magnetic field being parallel to the substrate and orthogonal to the axial magnetic field;
at least two magnetic field sources configured to generate an axial supplemental magnetic field and a radial supplemental magnetic field through the processing zone of the vacuum chamber; and
a magnetic field controller coupled to the magnetic field sensor and the at least two magnetic field sources, the magnetic field controller configured to adjust at least one characteristic of one or more of the axial supplemental magnetic field and the radial supplemental magnetic field based on the first signal and the second signal.

2. The apparatus of claim 1, wherein the magnetic field sensor is a wafer sensor placed within the processing zone of the vacuum chamber.

3. The apparatus of claim 2, wherein the wafer sensor comprises an array of magnetic field sensors configured to measure one or more parameters of the axial magnetic field and the radial magnetic field at a plurality of locations within the processing zone; and
wherein the magnetic field controller adjusts the at least one characteristic of the axial and radial supplemental magnetic fields based on the measured one or more parameters.

4. The apparatus of claim 1, wherein the magnetic field sensor is configured to measure a magnitude of the first signal representing the axial magnetic field and a magnitude of the second signal representing the radial magnetic field.

5. The apparatus of claim 4, wherein the at least one characteristic comprises one or more of a magnitude and a direction of the axial supplemental magnetic field and the radial supplemental magnetic field.

6. The apparatus of claim 5, wherein the at least two magnetic field sources comprise a first magnetic field source and a second magnetic field source that are parallel to each other, and wherein the magnetic field controller is configured to:
adjust one or more of current through the first magnetic field source and current through the second magnetic field source to adjust one or more of the magnitude and the direction of the axial supplemental magnetic field and the radial supplemental magnetic field.

7. The apparatus of claim 6, wherein the magnetic field controller is configured to:
adjust the current through the first magnetic field source independently of the current through the second magnetic field source.

8. The apparatus of claim 6, wherein the magnetic field controller is configured to:
adjust the current through the first magnetic field source and the current through the second magnetic field source until a ratio of the magnitude of the first signal representing the axial magnetic field and the magnitude of the second signal representing the radial magnetic field reaches a ratio threshold value.

9. The apparatus of claim 6, wherein the magnetic field controller is configured to:
adjust the current through the first magnetic field source and the current through the second magnetic field source until the magnitude of the first signal representing the axial magnetic field reaches a first threshold value and a magnitude of the second signal representing the radial magnetic field reaches a second threshold value.

10. The apparatus of claim wherein the at least one characteristic of one or more of the axial supplemental magnetic field and the radial supplemental magnetic field comprises one or more of
a number of windings in each of the at least two magnetic field sources;
a distance from a first of the at least two magnetic field sources to the substrate;
a distance from a second of the at least two magnetic field sources to the substrate; and
a distance between at least two magnetic field sources.

11. The apparatus of claim 1, wherein the at least two magnetic field sources comprise a plurality of coils, each coil comprising a plurality of windings.

12. The apparatus of claim 11, wherein the plurality of coils are mounted externally to the vacuum chamber.

13. The apparatus of claim 11, wherein at least one of the plurality of coils is mounted internally to the vacuum chamber.

14. The apparatus of claim 11, wherein the plurality of coils comprises at least four coils that are parallel to each other and the substrate, and wherein the magnetic field controller is configured to:
adjust current through each of the at least four coils independently, based on a magnitude of one or more of the axial supplemental magnetic field and the radial supplemental magnetic field measured by the magnetic field sensor.

15. The apparatus of claim 1, wherein the substrate processing apparatus further comprises a plasma density sensor coupled to the magnetic field controller and configured to measure density of the plasma within the vacuum chamber, and wherein the magnetic field controller is configured to:
adjust current through each of the at least two magnetic field sources independently, based on the measured density of the plasma.

16. A method for processing a substrate using a vacuum chamber, the method comprising:
detecting a first signal representing an axial magnetic field within a processing zone of the vacuum chamber, the processing zone for processing the substrate using plasma;
detecting a second signal representing a radial magnetic field within the processing zone, the radial magnetic field being parallel to the substrate and orthogonal to the axial magnetic field;
determining a magnitude of the first signal representing the axial magnetic field and a magnitude of the second signal representing the radial magnetic field at a plurality of locations within the processing zone; and
generating using at least two magnetic field sources, an axial supplemental magnetic field, and a radial supplemental magnetic field through the processing zone of the vacuum chamber based on the determined magnitudes of the first and second signals.

17. The method of claim 16, further comprising:
adjusting current through at least one of the at least two magnetic field sources, to adjust one or more of a magnitude and a direction of the axial supplemental magnetic field and the radial supplemental magnetic field.

18. The method of claim 17, further comprising:
adjusting the current through the at least one of the at least two magnetic field sources independently, until a ratio of the magnitude of the first signal representing the axial magnetic field and the magnitude of the second signal representing the radial magnetic field reaches a ratio threshold value.

19. The method of claim 17, further comprising:
adjusting the current through the at least one of the at least two magnetic field sources independently, until the magnitude of the first signal representing the axial magnetic field reaches a first threshold value and a magnitude of the second signal representing the radial magnetic field reaches a second threshold value.

20. A machine-readable storage medium including instructions that, when executed by a machine, cause the machine to perform operations comprising:
detecting a first signal representing an axial magnetic field within a processing zone of a vacuum chamber, the processing zone for processing a substrate using plasma;
detecting a second signal representing a radial magnetic field within the processing zone, the radial magnetic field being parallel to the substrate and orthogonal to the axial magnetic field;
determining a magnitude of the first signal representing the axial magnetic field and a magnitude of the second signal representing the radial magnetic field at a plurality of locations within the processing zone; and
generating using at least two magnetic field sources, an axial supplemental magnetic field, arid a radial supplemental magnetic field through the processing zone of the vacuum chamber based on the determined magnitudes of the first and second signals.

21. The machine-readable storage medium of claim 20, the operations further comprising:
adjusting one or more of current through a first magnetic field source of the at least two magnetic field sources and current through a second magnetic field source of the at least two magnetic field sources to adjust one or more of a magnitude and a direction of the axial supplemental magnetic field and the radial supplemental magnetic field.

22. The machine-readable storage medium of claim 21, the operations further comprising:
adjusting the current through the at least two magnetic field sources independently, until a ratio of the magnitude of the first signal representing the axial magnetic field and the magnitude of the second signal representing the radial magnetic field reaches a ratio threshold value.

23. The machine-readable storage medium of claim 21, the operations further comprising:
adjusting the current through the at least two magnetic field sources independently, until the magnitude of the first signal representing the axial magnetic field reaches a first threshold value and a magnitude of the second signal representing radial magnetic field reaches a second threshold value.
